(19) United States
(12) Patent Application Publication
(10) Pub. No.: US 2026/0198050 A1
(43) Pub. Date: Jul. 9, 2026

(54) METHOD FOR REDUCING POWER CONSUMPTION OF COMPLEMENTARY METAL OXIDE SEMICONDUCTOR AND TRANSISTOR THEREOF

(71) Applicant: FUH-CHENG JONG, TAINAN CITY (TW)

(72) Inventor: FUH-CHENG JONG, TAINAN CITY (TW)

(21) Appl. No.: 19/013,160

(22) Filed: Jan. 8, 2025

(51) Int. Cl. H10D 62/10; H10D 62/17; H10D 84/01; H10D 84/85

(52) U.S. Cl. CPC H10D 62/102; H10D 62/235; H10D 84/0165; H10D 84/85

(57) ABSTRACT

A method for reducing power consumption of a complementary metal oxide semiconductor and a transistor thereof are disclosed. The method includes configuring nMOS and pMOS as a complementary metal oxide semiconductor (CMOS); enabling that |VTN|+|VTP|≥(|VSP−VSN|)×90%, where VTN and VTP are the respective threshold voltages of nMOS and pMOS, and VSN and VSP are the respective source voltages of nMOS and pMOS, thereby reducing the power consumption of the complementary metal oxide semiconductor greatly.

### FIELD OF THE INVENTION

The present invention relates to a component and a circuit fabrication method for semiconductor integrated circuits, and more particularly to a component and a method for effectively reducing power consumption of a complementary metal-oxide-semiconductor (CMOS) due to switching operations and for lowering the temperature of chips.

### BACKGROUND OF THE INVENTION

To reduce the power consumption of chips, complementary metal-oxide-semiconductor (CMOS) technology has become the mainstream of integrated circuits, especially for chips composed of high-density transistors.

As chips are operated at a high frequency, according to the theory of dynamic power consumption, the power consumed by CMOS during signal switching (digital signal transitions) increases with the rise in frequency. Therefore, the conventional method for reducing the power consumption of CMOS is to lower the operating voltage of the chip.

Specifically, for example, Taiwan Patent Publication No. TW287278B discloses a full-scale enhanced MOS capacitor load driving circuit that uses two enhanced capacitors to enhance the switching speed of low-voltage deep-submicron CMOS very large-scale integrated circuits (VLSI). The aforementioned patent includes a basic part and an enhanced part. The basic part includes two P-type metal-oxide-semiconductor field-effect transistors (PMOS) and two N-type metal-oxide-semiconductor field-effect transistors (NMOS). The enhanced part includes two N-type metal-oxide-semiconductor field-effect transistors (NMOS) and two P-type metal-oxide-semiconductor field-effect transistors (PMOS). The output of the PMOS of the enhanced part is coupled with the NMOS and the NMOS and PMOS of the basic part, and each includes a capacitor to control the driving of NMOS of the basic part. The enhanced part further includes an inverter so that only one of the PMOS and NMOS is switched on during each transient period.

However, the aforementioned patent relies on the cooperation of multiple NMOS and PMOS to control upward or downward transients, resulting in complex operation and a large number of components, making it unsuitable for miniaturized chips.

### SUMMARY OF THE INVENTION

According to one aspect of the present invention, a method for reducing power consumption of a complementary metal oxide semiconductor is provided. The method comprises the following steps of: electrically connecting a gate of an N-type metal-oxide-semiconductor field-effect transistor and a gate of a P-type metal-oxide-semiconductor field-effect transistor to an input voltage, electrically connecting a source of the P-type metal-oxide-semiconductor field-effect transistor to a highest voltage; electrically connecting a drain of the N-type metal-oxide-semiconductor field-effect transistor to a drain of the P-type metal-oxide-semiconductor field-effect transistor, electrically connecting a source of the N-type metal-oxide-semiconductor field-effect transistor to a lowest voltage; enabling that |VTN|+|VTP|≥(|VSP−VSN|)*90%, where VTN is a threshold voltage of the N-type metal-oxide-semiconductor field-effect transistor, VTP is a threshold voltage of the P-type metal-oxide-semiconductor field-effect transistor, VSN is a source voltage of the N-type metal-oxide-semiconductor field-effect transistor, and VSP is a source voltage of the P-type metal-oxide-semiconductor field-effect transistor.

Preferably, the highest voltage is electrically connected to a power supply voltage, and the highest voltage is grounded.

Preferably, |VTN|+|VTP|=(|VSP−VSN|)*90%.

Preferably, the threshold voltage of the N-type metal-oxide-semiconductor field-effect transistor is changed and/or the threshold voltage of the P-type metal-oxide-semiconductor field-effect transistor is changed, such that |VTN|+|VTP|≥(|VSP−VSN|)*90%.

Preferably, a thickness of an oxide layer at the gate of the N-type metal-oxide-semiconductor field-effect transistor is changed and/or a thickness of an oxide layer at the gate of the P-type metal-oxide-semiconductor field-effect transistor is changed, thereby changing the threshold voltage of the N-type metal-oxide-semiconductor field-effect transistor and/or the threshold voltage of the P-type metal-oxide-semiconductor field-effect transistor.

Preferably, a channel impurity concentration of the N-type metal-oxide-semiconductor field-effect transistor is changed and/or a channel impurity concentration of the P-type metal-oxide-semiconductor field-effect transistor is changed, thereby changing the threshold voltage of the N-type metal-oxide-semiconductor field-effect transistor and/or the threshold voltage of the P-type metal-oxide-semiconductor field-effect transistor.

Preferably, a substrate impurity concentration of the N-type metal-oxide-semiconductor field-effect transistor is changed and/or a substrate impurity concentration of the P-type metal-oxide-semiconductor field-effect transistor is changed, thereby changing the threshold voltage of the N-type metal-oxide-semiconductor field-effect transistor and/or the threshold voltage of the P-type metal-oxide-semiconductor field-effect transistor.

Preferably, an energy difference between a gate material work function and a semiconductor work function of the N-type metal-oxide-semiconductor field-effect transistor is changed and/or an energy difference between a gate material work function and a semiconductor work function of the P-type metal-oxide-semiconductor field-effect transistor is changed, thereby changing the threshold voltage of the N-type metal-oxide-semiconductor field-effect transistor and/or the threshold voltage of the P-type metal-oxide-semiconductor field-effect transistor.

Preferably, a voltage difference between a substrate voltage and the source voltage of the N-type metal-oxide-semiconductor field-effect transistor is changed and/or a voltage difference between a substrate voltage and the source voltage of the P-type metal-oxide-semiconductor field-effect transistor is changed, thereby changing the threshold voltage of the N-type metal-oxide-semiconductor field-effect transistor and/or the threshold voltage of the P-type metal-oxide-semiconductor field-effect transistor.

According to another aspect of the present invention, a complementary metal oxide semiconductor for performing the foregoing method is provided. The complementary metal oxide semiconductor comprises an N-type metal-oxide-semiconductor field-effect transistor and a P-type metal-oxide-semiconductor field-effect transistor. A gate of the N-type metal-oxide-semiconductor field-effect transistor is electrically connected to an input voltage VG. A source of the N-type metal-oxide-semiconductor field-effect transistor is electrically connected to a lowest voltage. A gate of the P-type metal-oxide-semiconductor field-effect transistor is electrically connected to the input voltage VG. A source of the P-type metal-oxide-semiconductor field-effect transistor is electrically connected to a highest voltage. A drain of the N-type metal-oxide-semiconductor field-effect transistor is electrically connecting to a drain of the P-type metal-oxide-semiconductor field-effect transistor. A threshold voltage of the N-type metal-oxide-semiconductor field-effect transistor and/or a threshold voltage of the P-type metal-oxide-semiconductor field-effect transistor is changed through at least one of the following manners, such that |VTN|+|VTP|≥(|VSP−VSN|)*90%, where VTN is the threshold voltage of the N-type metal-oxide-semiconductor field-effect transistor, VTP is the threshold voltage of the P-type metal-oxide-semiconductor field-effect transistor, VSN is a source voltage of the N-type metal-oxide-semiconductor field-effect transistor, and VSP is a source voltage of the P-type metal-oxide-semiconductor field-effect transistor; A. changing a thickness of an oxide layer at the gate of the N-type metal-oxide-semiconductor field-effect transistor and/or changing a thickness of an oxide layer at the gate of the P-type metal-oxide-semiconductor field-effect transistor; B. changing a channel impurity concentration of the N-type metal-oxide-semiconductor field-effect transistor and/or changing a channel impurity concentration of the P-type metal-oxide-semiconductor field-effect transistor; C. changing a substrate impurity concentration of the N-type metal-oxide-semiconductor field-effect transistor and/or changing a substrate impurity concentration of the P-type metal-oxide-semiconductor field-effect transistor; D. changing an energy difference between a gate material work function and a semiconductor work function of the N-type metal-oxide-semiconductor field-effect transistor and/or changing an energy difference between a gate material work function and a semiconductor work function of the P-type metal-oxide-semiconductor field-effect transistor; E. changing a voltage difference between a substrate voltage and the source voltage of the N-type metal-oxide-semiconductor field-effect transistor and/or changing a voltage difference between a substrate voltage and the source voltage of the P-type metal-oxide-semiconductor field-effect transistor.

According to the above technical features, the following effects can be preferably achieved:

Through |VTN|+|VTP|≥(|VSP−VSN|)*90%, the power consumption of the complementary metal oxide semiconductor can be reduced greatly.

### BRIEF DESCRIPTION OF THE DRAWINGS

FIG. 1 is a flow block diagram according to a preferred embodiment of the present invention;

FIG. 2 is a first circuit diagram according to the preferred embodiment of the present invention, illustrating the overall architecture of the complementary metal oxide semiconductor;

FIG. 3 is a second circuit diagram according to the preferred embodiment of the present invention, illustrating the static power consumption of the complementary metal oxide semiconductor;

FIG. 4 is a third circuit diagram according to the preferred embodiment of the present invention, illustrating the dynamic power consumption of the complementary metal oxide semiconductor in a charging state;

FIG. 5 is a fourth circuit diagram according to the preferred embodiment of the present invention, illustrating the dynamic power consumption of the complementary metal oxide semiconductor in a discharging state;

FIG. 6 is a relationship diagram between the output voltage, the main current and the input voltage according to the preferred embodiment of the present invention, illustrating that the threshold voltage is 0.4 volts;

FIG. 7 is a relationship diagram between the output voltage, the main current and the input voltage according to the preferred embodiment of the present invention, illustrating that the threshold voltage is 0.5 volts; and

FIG. 8 is a relationship diagram between the output voltage, the main current and the input voltage according to the preferred embodiment of the present invention, illustrating that the threshold voltage is 0.6 volts.

### DESCRIPTION OF THE PREFERRED EMBODIMENTS

Embodiments of the present invention will now be described, by way of example only, with reference to the accompanying drawings.

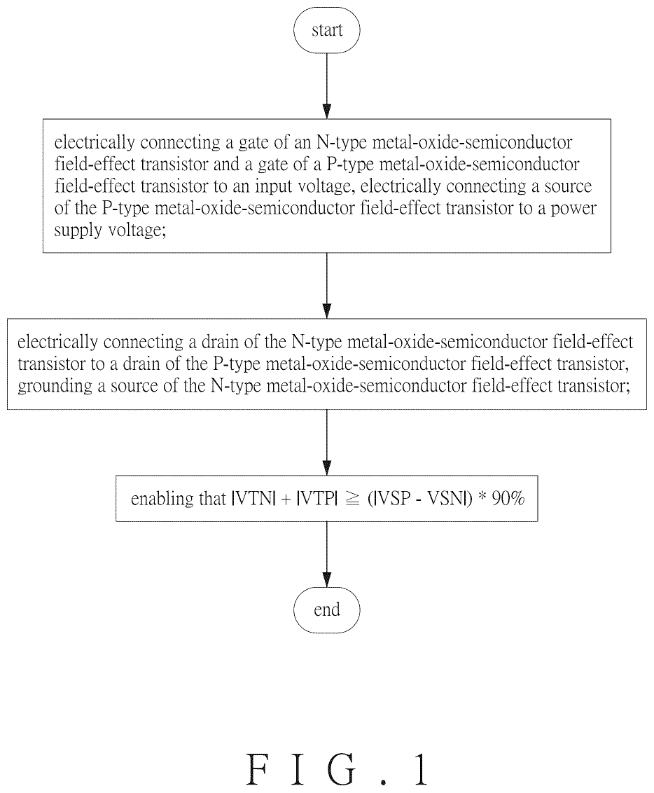

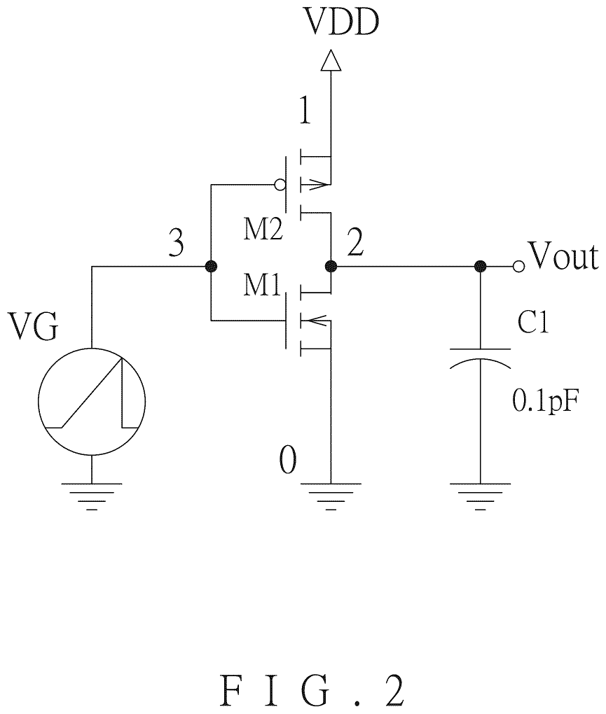

Referring to FIG. 1 and FIG. 2, the present invention discloses a complementary metal oxide semiconductor (CMOS) and a method for reducing power consumption of the complementary metal oxide semiconductor.

The complementary metal oxide semiconductor comprises an N-type metal-oxide-semiconductor field-effect transistor M1 and a P-type metal-oxide-semiconductor field-effect transistor M2.

The gate of the N-type metal-oxide-semiconductor field-effect transistor M1 is electrically connected to an input voltage VG. The source of the N-type metal-oxide-semiconductor field-effect transistor M1 is grounded.

The gate of the P-type metal-oxide-semiconductor field-effect transistor M2 is also electrically connected to the input voltage VG. The source of the P-type metal-oxide-semiconductor field-effect transistor M2 is electrically connected to a power supply voltage VDD.

In practical implementation, according to the configuration of the overall circuit of the complementary metal oxide semiconductor, the source of the N-type metal-oxide-semiconductor field-effect transistor M1 may be electrically connected to the lowest voltage of the entire complementary metal oxide semiconductor. The source of the P-type metal-oxide-semiconductor field-effect transistor M2 may be electrically connected to the highest voltage of the entire complementary metal oxide semiconductor.

The drain of the N-type metal-oxide-semiconductor field-effect transistor M1 is electrically connected to the drain of the P-type metal-oxide-semiconductor field-effect transistor M2, outputting an output voltage Vout and electrically connected to the sum of a load capacitance and a parasitic capacitance, that is, a load capacitance and parasitic capacitance C1.

In practical implementation, multiple sets of N-type metal-oxide-semiconductor field-effect transistors M1 and P-type metal-oxide-semiconductor field-effect transistors M2 may be connected in parallel to form a more complex complementary metal oxide semiconductor. The preferred embodiment of the present invention takes a single set as an example.

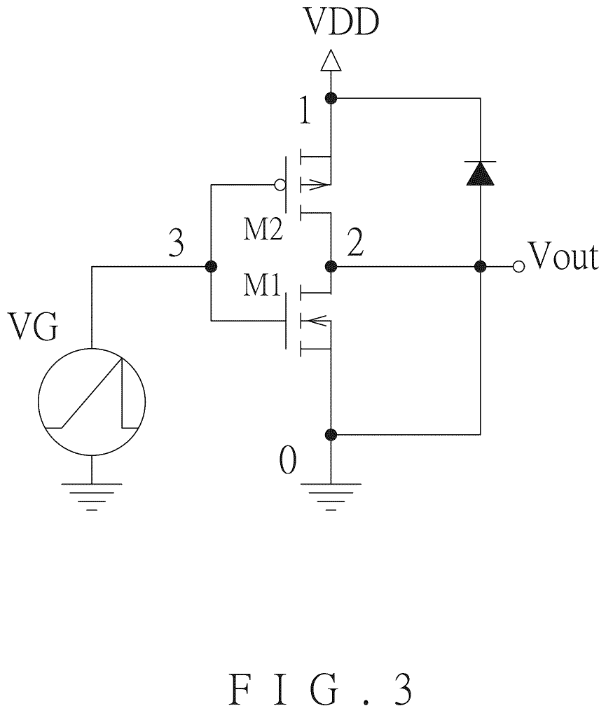

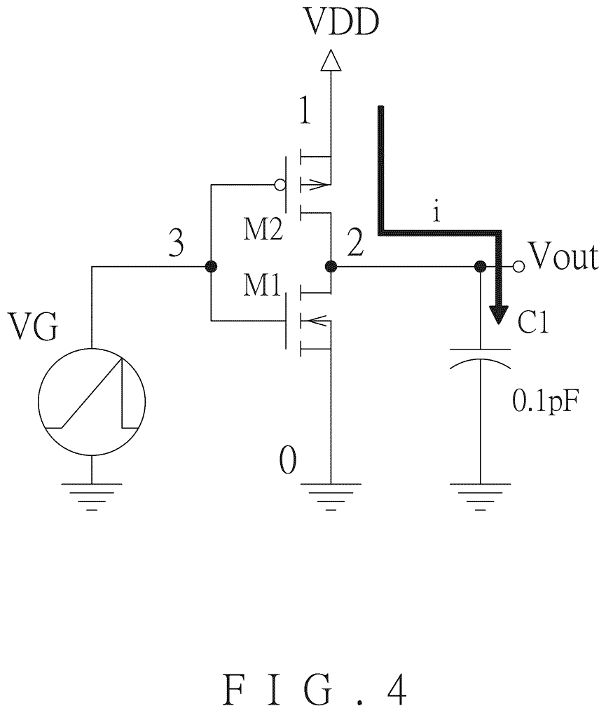

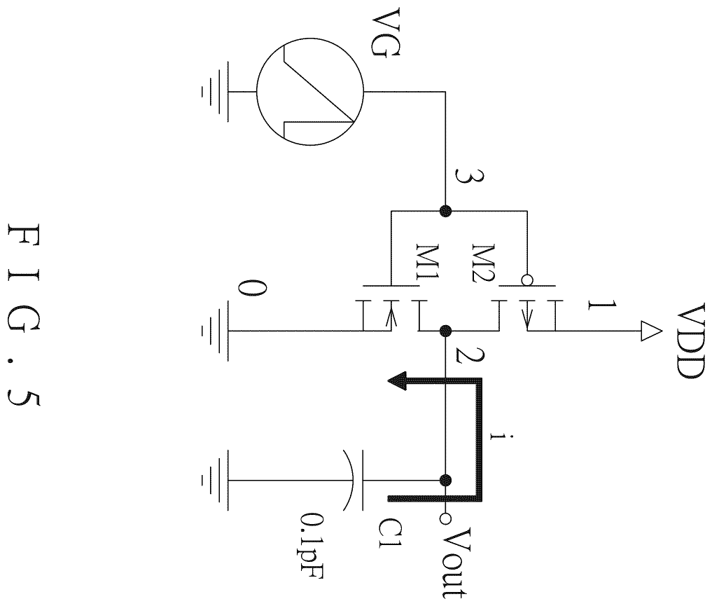

Referring to FIG. 3 through FIG. 5, the power consumption of the complementary metal oxide semiconductor is mainly divided into static power consumption as shown in FIG. 3 and dynamic power consumption as shown in FIG. 4 and FIG. 5.

Static power consumption is caused by leakage current, while dynamic power consumption is related to the charging and discharging state during output transitions and the switching frequency of the circuit, resulting in a short-circuit current i. In charging and discharging states, power consumption increases as the frequency rises.

Please refer to FIG. 2 and Table 1 below. According to the input conditions in different regions in Table 1, Table 1 shows that in different regions, the N-type metal-oxide-semiconductor field-effect transistor M1 and the P-type metal-oxide-semiconductor field-effect transistor M2 each operate in a linear, saturation or cut-off state.

In Table 1, nMOS is the N-type metal-oxide-semiconductor field-effect transistor M1, pMOS is the P-type metal-oxide-semiconductor field-effect transistor M2, Vin is the input voltage VG, VDD is the power supply voltage VDD, VTHn is the threshold voltage of the N-type metal-oxide-semiconductor field-effect transistor M1, and VTHp is the threshold voltage of the P-type metal-oxide-semiconductor field-effect transistor M1.

TABLE 1

| region | input condition | pMOS | nMOS |
|---|---|---|---|
| I | 0 ≤ Vᵢₙ ≤ V_{THn} | linear | cut-off |
| II | V_{THn} ≤ Vᵢₙ < 0.5 V_{DD} | linear | saturation |
| III | Vᵢₙ = 0.5 V_{DD} | saturation | saturation |
| IV | 0.5 V_{DD} < Vᵢₙ ≤ V_{DD} − V_{THp} | saturation | linear |
| V | Vᵢₙ ≥ V_{DD} − V_{THp} | cut-off | linear |

Since the complementary metal oxide semiconductor has an inverted gate structure, in the region I and region V, one or both of the N-type metal-oxide-semiconductor field-effect transistor M1 and the P-type metal-oxide-semiconductor field-effect transistor respectively M2 remain in the cut-off state. The current of the supply voltage VDD consists only of the reverse saturation current between the drain and the substrate, so the entire circuit consumes almost no power.

In the region II, region III and region IV, the main current is always conducted. In the region III, the main current reaches the maximum value. The aforementioned main current refers to Ip, that is, the current flowing from the power supply voltage VDD through the N-type metal-oxide-semiconductor field-effect transistor M1 and the P-type metal-oxide-semiconductor field-effect transistor M2, not limited to the drain current of one of them.

Therefore, in order to reduce the power consumption of the complementary metal oxide semiconductor, it is necessary to maximize the region I and region V and to minimize the region II, region III and region IV where the main current flows.

Since the complementary metal oxide semiconductor generates the main current only in the region II, region III and region IV, if the power supply voltage VDD is assumed to be 1 volt, the threshold voltage of the N-type metal-oxide-semiconductor field-effect transistor M1 will 0.5 volts, the threshold voltage of the P-type metal-oxide-semiconductor field-effect transistor M2 will-0.5 volts, and the region II, region III, and region IV will not exist, thereby eliminating the power consumption caused by the main current in the complementary metal oxide semiconductor.

Using LTSpice XVII for circuit simulation under the condition that the power supply voltage VDD is 1 volt:

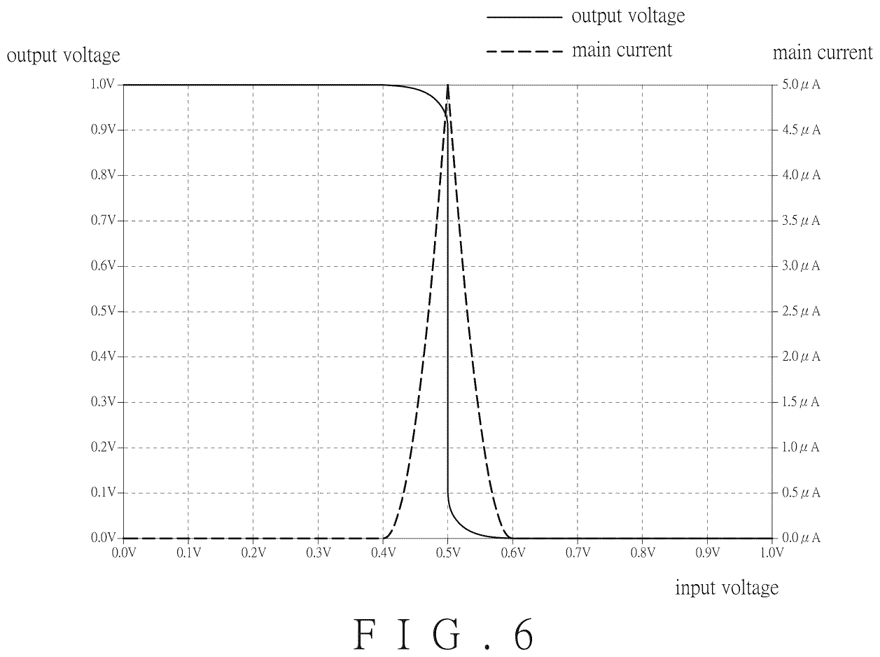

If the threshold voltage of the N-type metal-oxide-semiconductor field-effect transistor M1 is set to be 0.4 volts and the threshold voltage of the P-type metal-oxide-semiconductor field-effect transistor M2 is set to be −0.4 volts, the simulation result is shown in FIG. 6.

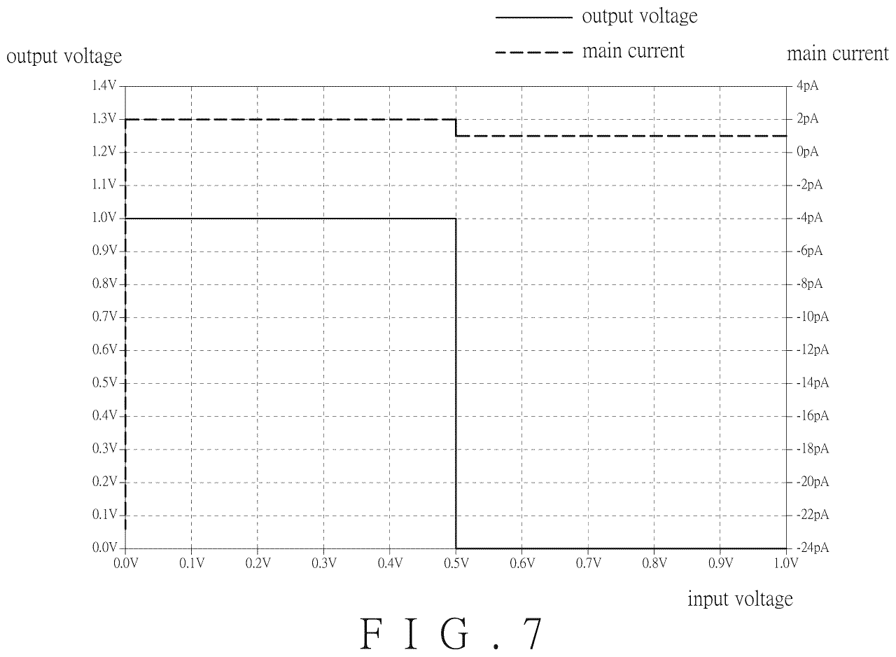

If the threshold voltage of the N-type metal-oxide-semiconductor field-effect transistor M1 is set to be 0.5 volts and the threshold voltage of the P-type metal-oxide-semiconductor field-effect transistor M2 is set to be −0.5 volts, the simulation result is shown in FIG. 7.

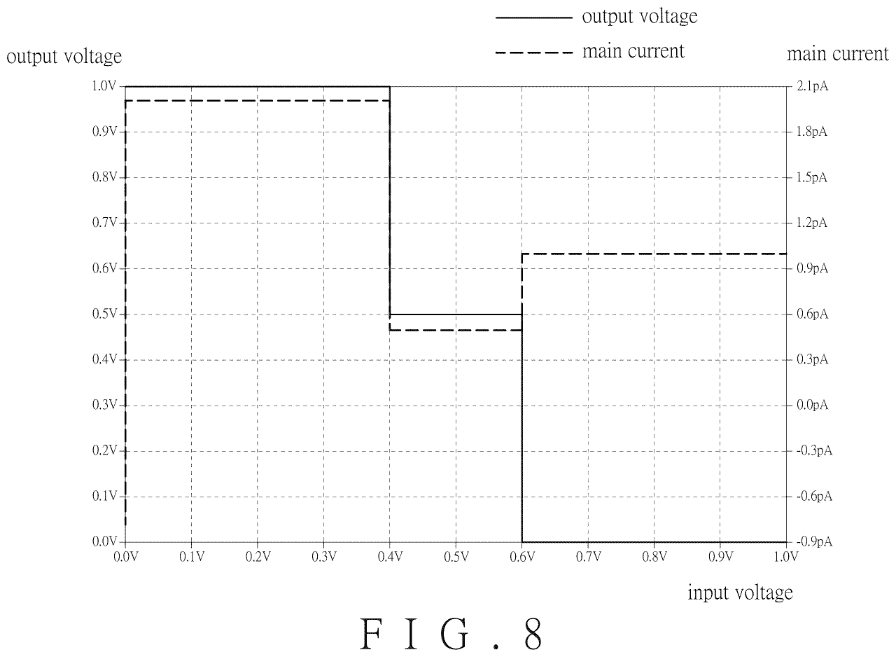

If the threshold voltage of the N-type metal-oxide-semiconductor field-effect transistor M1 is set to be 0.6 volts and the threshold voltage of the P-type metal-oxide-semiconductor field-effect transistor M2 is set to be −0.6 volts, the simulation result is shown in FIG. 8.

As shown in FIG. 6, the main current begins to flow when the input voltage VG is between 0.4 and 0.6 volts, and the main current reaches the maximum of 5 microamps (10-6 amperes) when the input voltage VG is 0.5 volts.

As shown in FIG. 7, when the input voltage VG is 0.5 volts, the main current of 2 picoamps (10-12 amperes) begins to flow. The current of 2 picoamps (10-12 amperes) should actually be the reverse saturation current between the drain and the substrate. The complementary metal oxide semiconductor does not generate the main current due to signal exchange, that is, the power consumption is almost zero.

As shown in FIG. 8, when the input voltage VG is between 0.4 and 0.6 volts, the main current begins to flow, the main current is 0.5 to 1 picoamps (10-12 amperes), which should actually be the reverse saturation current between the drain and the substrate. The complementary metal oxide semiconductor does not generate the main current due to signal exchange, that is, the power consumption is almost zero.

From the above simulation results, it can be concluded that if 90% of the absolute value of the voltage difference between the highest voltage at the source of the P-type metal-oxide-semiconductor field-effect transistor M2 and the lowest voltage at the source of the N-type metal-oxide-semiconductor field-effect transistor M1 does not exceed the sum of the absolute values of the threshold voltage s of the N-type metal-oxide-semiconductor field-effect transistor M1 and the P-type metal-oxide-semiconductor field-effect transistor M2, the power consumption of the complementary metal oxide semiconductor can be minimized.

Referring to FIG. 1 and FIG. 2, according to the above simulation results, the method for reducing the power consumption of the complementary metal oxide semiconductor, in addition to the configuration of the complementary metal oxide semiconductor, the sum of the absolute values of the threshold voltages of the N-type metal-oxide-semiconductor field-effect transistor M1 and the P-type metal-oxide-semiconductor field-effect transistor M2 should not be less than 90% of the absolute value of the voltage difference between the voltage at the source of the N-type metal-oxide-semiconductor field-effect transistor M1 and the voltage at the source of the P-type metal-oxide-semiconductor field-effect transistor M2. Preferably, the sum should fall within the range of 90% to 110% of the absolute value of the voltage difference.

For example, if the threshold voltage of the N-type metal-oxide-semiconductor field-effect transistor M1 is 0.5 volts and the threshold voltage of the P-type metal-oxide-semiconductor field-effect transistor M2 is-0.5 volts, the sum of the absolute values of two is 1 volt. At this time, the voltage at the source of the N-type metal-oxide-semiconductor field-effect transistor M1 and the voltage at the source of the P-type metal-oxide-semiconductor field-effect transistor M2 can be respectively selected from, for example, 0.3 volts, −0.7 volts, or −0.3 volts, −1.3 volts. Because either |−0.7−0.3| or |−1.3−(−0.3)| will be equal to 1, which meets the conditions used in the method for reducing the power consumption of the complementary metal oxide semiconductor. These values are only examples.

In this way, the power consumption of the complementary metal oxide semiconductor can be reduced greatly. When the equal sign holds, more power consumption can be reduced.

Taking the preferred embodiment of the present invention as an example, the decrease in amperage from a few microamps (10⁻⁶ amperes) in FIG. 6 to a few picoamps (10⁻¹² amperes) in FIG. 8 is a difference of about one million times. The method for reducing the power consumption of the complementary metal oxide semiconductor is undoubtedly an important milestone in today's society, where the energy crisis is becoming more and more serious.

According to the threshold voltage calculation formula of the metal-oxide-semiconductor field-effect transistor, the threshold voltage of the N-type metal-oxide-semiconductor field-effect transistor M1 and/or the threshold voltage of the P-type metal-oxide-semiconductor field-effect transistor M2 can be changed in the following manners, such that the sum of the absolute values of the threshold voltage s of the N-type metal-oxide-semiconductor field-effect transistor M1 and the P-type metal-oxide-semiconductor field-effect transistor M2 is not less than 90% of the absolute value of the voltage difference between the voltage at the source of the N-type metal-oxide-semiconductor field-effect transistor M1 and the voltage at the source of the P-type metal-oxide-semiconductor field-effect transistor M2.

A. Changing the thickness of the oxide layer at the gate of the N-type metal-oxide-semiconductor field-effect transistor M1 and/or changing the thickness of the oxide layer at the gate of the P-type metal-oxide-semiconductor field-effect transistor M2, thereby changing the threshold voltage of the N-type metal-oxide-semiconductor field-effect transistor M1 and/or the threshold voltage of the P-type metal-oxide-semiconductor field-effect transistor M2.

B. Changing the channel impurity concentration of the N-type metal-oxide-semiconductor field-effect transistor M1 and/or changing the channel impurity concentration of the P-type metal-oxide-semiconductor field-effect transistor M2, thereby changing the threshold voltage of the N-type metal-oxide-semiconductor field-effect transistor M1 and/or the threshold voltage of the P-type metal-oxide-semiconductor field-effect transistor M2.

C. Changing the substrate impurity concentration of the N-type metal-oxide-semiconductor field-effect transistor M1 and/or changing the substrate impurity concentration of the P-type metal-oxide-semiconductor field-effect transistor M2, thereby changing the threshold voltage of the N-type metal-oxide-semiconductor field-effect transistor M1 and/or the threshold voltage of the P-type metal-oxide-semiconductor field-effect transistor M2.

D. Changing the energy difference (q φₘₛ) between the gate material work function (q om) and the semiconductor work function (qφₛ) of the N-type metal-oxide-semiconductor field-effect transistor M1 and/or changing the energy difference between the gate material work function and the semiconductor work function of the P-type metal-oxide-semiconductor field-effect transistor M2 that is flatband voltage, thereby changing the threshold voltage of the N-type metal-oxide-semiconductor field-effect transistor M1 and/or the threshold voltage of the P-type metal-oxide-semiconductor field-effect transistor M2.

E. Changing the voltage difference between the substrate voltage and the source voltage of the N-type metal-oxide-semiconductor field-effect transistor M1 and/or changing the voltage difference between the substrate voltage and the source voltage of the P-type metal-oxide-semiconductor field-effect transistor M2, thereby changing the threshold voltage of the N-type metal-oxide-semiconductor field-effect transistor M1 and/or the threshold voltage of the P-type metal-oxide-semiconductor field-effect transistor M2.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A method for reducing power consumption of a complementary metal oxide semiconductor, comprising the following steps of:
electrically connecting a gate of an N-type metal-oxide-semiconductor field-effect transistor and a gate of a P-type metal-oxide-semiconductor field-effect transistor to an input voltage, electrically connecting a source of the P-type metal-oxide-semiconductor field-effect transistor to a highest voltage;
electrically connecting a drain of the N-type metal-oxide-semiconductor field-effect transistor to a drain of the P-type metal-oxide-semiconductor field-effect transistor, electrically connecting a source of the N-type metal-oxide-semiconductor field-effect transistor to a lowest voltage;
enabling that |VTN|+|VTP|≥(|VSP−VSN|)*90%, where VTN is a threshold voltage of the N-type metal-oxide-semiconductor field-effect transistor, VTP is a threshold voltage of the P-type metal-oxide-semiconductor field-effect transistor, VSN is a source voltage of the N-type metal-oxide-semiconductor field-effect transistor, and VSP is a source voltage of the P-type metal-oxide-semiconductor field-effect transistor.

2. The method as claimed in claim 1, wherein the highest voltage is electrically connected to a power supply voltage, and the highest voltage is grounded.

3. The method as claimed in claim 1, wherein |VTN|+|VTP|=(|VSP−VSN|)*90%.

4. The method as claimed in claim 1, wherein the threshold voltage of the N-type metal-oxide-semiconductor field-effect transistor is changed and/or the threshold voltage of the P-type metal-oxide-semiconductor field-effect transistor is changed, such that |VTN|+|VTP|≥(|VSP−VSN|)*90%.

5. The method as claimed in claim 4, wherein a thickness of an oxide layer at the gate of the N-type metal-oxide-semiconductor field-effect transistor is changed and/or a thickness of an oxide layer at the gate of the P-type metal-oxide-semiconductor field-effect transistor is changed, thereby changing the threshold voltage of the N-type metal-oxide-semiconductor field-effect transistor and/or the threshold voltage of the P-type metal-oxide-semiconductor field-effect transistor.

6. The method as claimed in claim 4, wherein a channel impurity concentration of the N-type metal-oxide-semiconductor field-effect transistor is changed and/or a channel impurity concentration of the P-type metal-oxide-semiconductor field-effect transistor is changed, thereby changing the threshold voltage of the N-type metal-oxide-semiconductor field-effect transistor and/or the threshold voltage of the P-type metal-oxide-semiconductor field-effect transistor.

7. The method as claimed in claim 4, wherein a substrate impurity concentration of the N-type metal-oxide-semiconductor field-effect transistor is changed and/or a substrate impurity concentration of the P-type metal-oxide-semiconductor field-effect transistor is changed, thereby changing the threshold voltage of the N-type metal-oxide-semiconductor field-effect transistor and/or the threshold voltage of the P-type metal-oxide-semiconductor field-effect transistor.

8. The method as claimed in claim 4, wherein an energy difference between a gate material work function and a semiconductor work function of the N-type metal-oxide-semiconductor field-effect transistor is changed and/or an energy difference between a gate material work function and a semiconductor work function of the P-type metal-oxide-semiconductor field-effect transistor is changed, thereby changing the threshold voltage of the N-type metal-oxide-semiconductor field-effect transistor and/or the threshold voltage of the P-type metal-oxide-semiconductor field-effect transistor.

9. The method as claimed in claim 4, wherein a voltage difference between a substrate voltage and the source voltage of the N-type metal-oxide-semiconductor field-effect transistor is changed and/or a voltage difference between a substrate voltage and the source voltage of the P-type metal-oxide-semiconductor field-effect transistor is changed, thereby changing the threshold voltage of the N-type metal-oxide-semiconductor field-effect transistor and/or the threshold voltage of the P-type metal-oxide-semiconductor field-effect transistor.

10. A complementary metal oxide semiconductor for performing the method as claimed in claim 1, comprising an N-type metal-oxide-semiconductor field-effect transistor and a P-type metal-oxide-semiconductor field-effect transistor;
a gate of the N-type metal-oxide-semiconductor field-effect transistor being electrically connected to an input voltage VG, a source of the N-type metal-oxide-semiconductor field-effect transistor being electrically connected to a lowest voltage;
a gate of the P-type metal-oxide-semiconductor field-effect transistor being electrically connected to the input voltage VG, a source of the P-type metal-oxide-semiconductor field-effect transistor being electrically connected to a highest voltage, a drain of the N-type metal-oxide-semiconductor field-effect transistor being electrically connecting to a drain of the P-type metal-oxide-semiconductor field-effect transistor;
wherein a threshold voltage of the N-type metal-oxide-semiconductor field-effect transistor and/or a threshold voltage of the P-type metal-oxide-semiconductor field-effect transistor is changed through at least one of the following manners, enabling that |VTN|+|VTP|≥(|VSP−VSN|)*90%, where VTN is the threshold voltage of the N-type metal-oxide-semiconductor field-effect transistor, VTP is the threshold voltage of the P-type metal-oxide-semiconductor field-effect transistor, VSN is a source voltage of the N-type metal-oxide-semiconductor field-effect transistor, and VSP is a source voltage of the P-type metal-oxide-semiconductor field-effect transistor;
A. changing a thickness of an oxide layer at the gate of the N-type metal-oxide-semiconductor field-effect transistor and/or changing a thickness of an oxide layer at the gate of the P-type metal-oxide-semiconductor field-effect transistor;
B. changing a channel impurity concentration of the N-type metal-oxide-semiconductor field-effect transistor and/or changing a channel impurity concentration of the P-type metal-oxide-semiconductor field-effect transistor;
C. changing a substrate impurity concentration of the N-type metal-oxide-semiconductor field-effect transistor and/or changing a substrate impurity concentration of the P-type metal-oxide-semiconductor field-effect transistor;
D. changing an energy difference between a gate material work function and a semiconductor work function of the N-type metal-oxide-semiconductor field-effect transistor and/or changing an energy difference between a gate material work function and a semiconductor work function of the P-type metal-oxide-semiconductor field-effect transistor;
E. changing a voltage difference between a substrate voltage and the source voltage of the N-type metal-oxide-semiconductor field-effect transistor and/or changing a voltage difference between a substrate voltage and the source voltage of the P-type metal-oxide-semiconductor field-effect transistor.
